(19) United States
(12) Patent Application Publication
(10) Pub. No.: US 2021/0006036 A1
(43) Pub. Date: Jan. 7, 2021

(54) OPTICAL MODULE

(71) Applicant: Mitsubishi Electric Corporation, Tokyo (JP)

(72) Inventors: Akio SHIRASAKI, Tokyo (JP); Tatsuki OTANI, Tokyo (JP); Norio OKADA, Tokyo (JP)

(73) Assignee: Mitsubishi Electric Corporation, Tokyo (JP)

(21) Appl. No.: 16/969,441

(22) PCT Filed: Apr. 16, 2018
(86) PCT No.: PCT/JP2018/015692

§ 371 Date: Aug. 12, 2020

(51) Int. Cl. H01S 5/0683; H01S 5/024; H01S 5/022

(52) U.S. Cl. CPC H01S 5/0683; H01S 5/02288; H01S 5/02415

(57) ABSTRACT

An optical module includes a semiconductor laser element, a lens configured to collect emitted light that is emitted from the semiconductor laser element, a cap configured to hold the lens and hermetically seal the semiconductor laser element, a monitor light-receiving element configured to receive backlight of the semiconductor laser element, a transmission plate arranged between the semiconductor laser element and the monitor light-receiving element and configured to attenuate the backlight according to decrease in a temperature around the cap so as to cause the backlight to enter the monitor light-receiving element, and a control unit configured to control an injection current of the semiconductor laser element such that an output of the monitor light-receiving element is kept at a constant level.

### FIELD

The present invention relates to an optical module.

### BACKGROUND

In recent years, optical modules that support a transmission distance of 40 to 80 km at a transmission speed of 10 Gbit/s have become widely used, and demands for cost reduction thereof have been increasing. Such an optical module includes, for example, an electroabsorption modulator, a semiconductor laser element capable of transmitting a high-quality light signal, and a Peltier element that controls the temperature of the semiconductor laser element at a constant level to stabilize the characteristics. As a package of the optical module, conventionally ceramic box packages were used but, recently, cheaper TO-CAN (transistor outlined CAN) packages have been used.

TO-CAN packages hermetically seal a semiconductor laser element by resistance welding of a cylindrical cap to a stem with a lens attached to the cap. Front light of a laser diode is focused on the end surface of an optical fiber via the lens. By virtue of this, the front light of the semiconductor laser element is coupled into the waveguide of the optical fiber and a light signal is transmitted. Backlight of the semiconductor laser element is, for example, made to enter a monitor light-receiving element such as a photo diode. The monitor light-receiving element outputs a photocurrent according to the amount of received light. An injection current to the semiconductor laser element is controlled such that this photocurrent has a constant value, and the output of the light signal that the semiconductor laser element transmits is maintained at a constant level. This is called APC (auto power control).

The characteristics of the semiconductor laser element sensitively change depending on the temperature. In order to stably transmit high-quality light signal, the temperature of the semiconductor laser element is controlled such that it remains at a constant level by a thermoelectric cooling module (TEC). TEC is a thermoelectric module that has a heat absorption substrate and a heat dissipation substrate having good thermal conductivity and attached to one end and the other end, respectively, of a Peltier element.

When the package ambient temperature changes from room temperature to high temperature, the position of the semiconductor laser element whose temperature is controlled by the TEC hardly changes, but the cap whose temperature is not controlled by the TEC thermally expands. This thermal expansion causes the position of the lens to be displaced in the direction toward the optical fiber. As a result, the focal point of the front light of the semiconductor laser element is displaced in the direction toward the lens, which causes the coupling efficiency into the optical fiber to fluctuate. When the coupling efficiency into the optical fiber fluctuates, the intensity (Pf) of the light signal coupled into the optical fiber will also change. Such a change in the light signal intensity Pf due to the ambient temperature change is called tracking error.

The patent literature PTL 1 illustrates a TO-CAN package in which another lens is arranged between the semiconductor laser element and the lens. This TO-CAN package reduces the tracking error by shaping the emitted light emitted by the semiconductor laser element as collimated light.

### PRIOR ART

### Patent Literature

[PTL 1] JP 2011-108937A

### SUMMARY

### Technical Problem

The package of the TO-CAN type illustrated in PTL 1 requires highly accurate fixing of the position of the lens for generation of the collimated light, which leads to increase in assembly cost.

The present invention has been made to solve the above-described problem and an object of the present invention is to provide an optical module that reduces the tracking error.

### Means for Solving the Problems

According to a present invention, an optical module includes a semiconductor laser element, a lens configured to collect emitted light that is emitted from the semiconductor laser element, a cap configured to hold the lens and hermetically seal the semiconductor laser element, a monitor light-receiving element configured to receive backlight of the semiconductor laser element, a transmission plate arranged between the semiconductor laser element and the monitor light-receiving element and configured to attenuate the backlight according to decrease in a temperature around the cap so as to cause the backlight to enter the monitor light-receiving element, and a control unit configured to control an injection current of the semiconductor laser element such that an output of the monitor light-receiving element is kept at a constant level.

Other features will be disclosed below.

### Advantageous Effects of Invention

According to this invention, since the backlight that has passed through the transmission plate whose transmittance varies according to temperature is received by the monitor light-receiving element, it is made possible to obtain an optical module that reduces tracking error.

### BRIEF DESCRIPTION OF THE DRAWINGS

FIG. 1 is a cross-sectional view of an optical module in accordance with the first embodiment.

FIG. 2 is a cross-sectional view of an optical module in accordance with the first embodiment.

FIG. 3 is a diagram that shows a characteristic of the transmission plate.

FIG. 4 is a block diagram that illustrates control method of the optical module.

FIG. 5 is a diagram that shows temperature dependence of the light signal intensity.

FIG. 6 is a diagram that illustrates part of the optical module in accordance with the third embodiment.

FIG. 7 is a diagram that shows the relationship between the incidence angle and the reflectance.

FIG. 8 is a diagram that illustrates part of the optical module in accordance with the fourth embodiment.

FIG. 9 is a view of the optical module in accordance with the fifth embodiment.

FIG. 10 is a view of the optical module in accordance with the sixth embodiment.

### DESCRIPTION OF EMBODIMENTS

An optical module in accordance with an embodiment of the present invention will be described with reference to the drawings. The same or corresponding components are denoted by the same reference signs and description thereof may not be repeated.

### First Embodiment

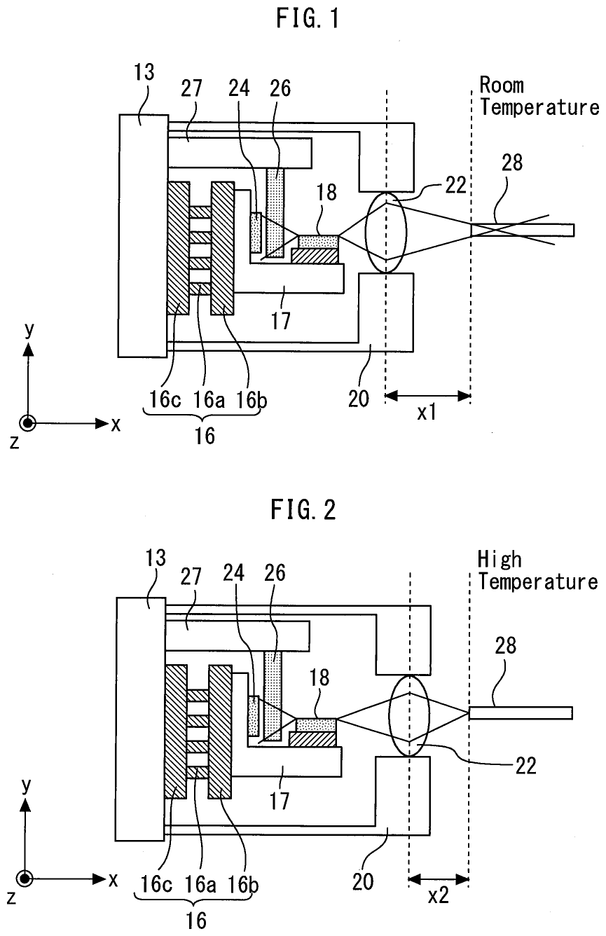

FIG. 1 is a cross-sectional view of an optical module 10 in accordance with the first embodiment. The optical module 10 includes a stem 13. Provided in the stem 13 is a thermoelectric cooler 16. The thermoelectric cooler 16 can be configured as a thermoelectric cooler (TEC) having a heat absorption substrate 16b and a heat dissipation substrate 16c attached to one side and the other sides, respectively, of a Peltier element 16a. The heat dissipation substrate 16c is fixed to the stem 13. Although the fixing method is not particularly limited, for example, soldering using AuSn, SnAgCu, etc. may be mentioned. Alternatively, welding may be used.

Attached to the thermoelectric cooler 16 is a semiconductor laser element 18, which is attached thereto by a heat dissipation block 17 and the like. Specifically, the semiconductor laser element 18 is attached to the heat absorption substrate 16b by the heat dissipation block 17 and the like. The semiconductor laser element 18 is, for example, a laser diode. The semiconductor laser element 18 is subjected to the temperature adjustment by the thermoelectric cooler 16. By providing a power supply lead pin penetrating the stem 13, electrical power can be supplied to the semiconductor laser element 18 and the thermoelectric cooler 16. In order to adjust the temperature of the semiconductor laser element 18 by the thermoelectric cooler 16 such that the temperature remains at a constant level, it is ensured that a light signal that the semiconductor laser element 18 outputs has high quality.

A cap 20 is fixed to the stem 13. The cap 20 hermetically seals the thermoelectric cooler 16 and the semiconductor laser element 18. Further, the cap 20 holds a lens 22. The lens 22 collects emitted light emitted from the semiconductor laser element 18. For example, by resistance welding of the cap 20 holding the lens 22 onto the stem 13, the semiconductor laser element 18 can be hermetically sealed.

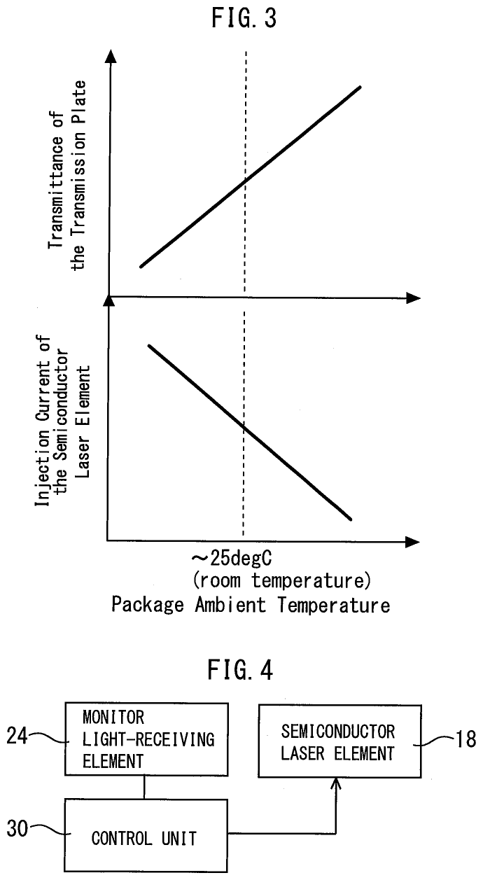

Provided in the heat dissipation block 17 is a monitor light-receiving element 24 that receives backlight of the semiconductor laser element 18. The monitor light-receiving element 24 is, for example, an element that converts light into current such as a photodiode. Between the semiconductor laser element 18 and the monitor light-receiving element 24, a transmission plate 26 is arranged. The transmission plate 26 attenuates the backlight of the semiconductor laser element 18. The transmission plate 26 attenuates the backlight according to decrease in the temperature around the cap 20 and then causes it to enter the monitor light-receiving element 24. Material of the transmission plate 26 may be selected, for example, from borosilicate crown glass, synthetic quartz, and glass ceramics, which are optical components available at low cost. The graph in the upper section of FIG. 3 shows the relationship between the package ambient temperature and the transmittance of a reflective plate. The term “package” refers to the component that covers the optical module and refers to the cap 20 in this embodiment. When the package ambient temperature goes down, then the temperature of the transmission plate 26 also goes down, so that the transmittance of the transmission plate 26 is decreased.

As illustrated in FIG. 1, the transmission plate 26 is held by a metal post 27. The metal post 27 is fixed to the stem 13. Accordingly, since the transmission plate 26 is not in thermal contact with the thermoelectric cooler 16, the transmission plate 26 does not experience any temperature change by the thermoelectric cooler 16, so that the transmittance of the transmission plate 26 does not change. In other words, the temperature of the transmission plate 26 is determined solely by the temperature around the cap 20.

On the outside of the cap 20, an optical fiber 28 is provided. The optical fiber 28 is provided at a position where optical coupling takes place with the emitted light collected by the lens 22. The emitted light of the semiconductor laser element 18 at “room temperature” and the position of the optical fiber 28 are depicted in FIG. 1. When the temperature around the optical module corresponds to the room temperature, the end surface position of the optical fiber 28 in the optical axis direction is defocused in the direction toward the lens 22.

FIG. 2 depicts the emitted light of the semiconductor laser element 18 at the time of high temperature where the temperature is higher than the room temperature and the position of the optical fiber 28. When the ambient temperature of the optical module 10 rises to a high temperature, then the cap 20 thermally expands, and the position of the lens 22 is displaced in the direction toward the optical fiber 28. As a result, the distance x2 between the optical fiber 28 and the lens 22 of FIG. 2 becomes shorter than the distance x1 between the optical fiber 28 and the lens 22 of FIG. 1. Consequently, the focal point of the emitted light of the semiconductor laser element 18 is displaced in the direction toward the lens 22. As a result, the focal point of the emitted light and the end surface position of the optical fiber 28 become closer to each other. In this state, the focal point of the emitted light and the end surface position of the optical fiber 28 generally agree with each other, and the peak of the coupling efficiency is obtained.

FIG. 4 is a block diagram that illustrates control of the injection current of the semiconductor laser element 18. When the monitor light-receiving element 24 receives, via the transmission plate 26, the backlight of the semiconductor laser element 18, then the optical current corresponding thereto is provided as the output of the monitor light-receiving element 24 to the control unit 30. The control unit 30 controls the injection current of the semiconductor laser element 18 such that the output of the monitor light-receiving element 24 becomes constant. Accordingly, the emitted light of the semiconductor laser element 18 or the intensity of the light signal is APC (automatic power control) controlled.

As illustrated in the upper section of FIG. 3, the transmittance of the transmission plate 26 becomes smaller as the temperature becomes lower. Accordingly, at the time of high temperature, the backlight that is transmitted through the transmission plate 26 is strong, and, at the time of low temperature, the backlight that is transmitted through the transmission plate 26 becomes weak. As a result, when the control unit 30 controls the injection current of the semiconductor laser element 18 such that the output of the monitor light-receiving element 24 becomes constant, then the injection current of the semiconductor laser element 18 becomes large at the time of low temperature and the same injection current becomes small at the time of high temperature. For example, illustrated at the lower section of FIG. 3 is the relationship between the package ambient temperature and the injection current of the semiconductor laser element. In response to decrease in the temperature around the package, the transmittance of the transmission plate 26 decreases, so that the intensity of the backlight that the monitor light-receiving element 24 receives is decreased. In this state, the control unit 30 increases the injection current of the semiconductor laser element 18 such that the optical current output by the monitor light-receiving element 24 is not changed. In other words, the lower the temperature, the higher the injection current.

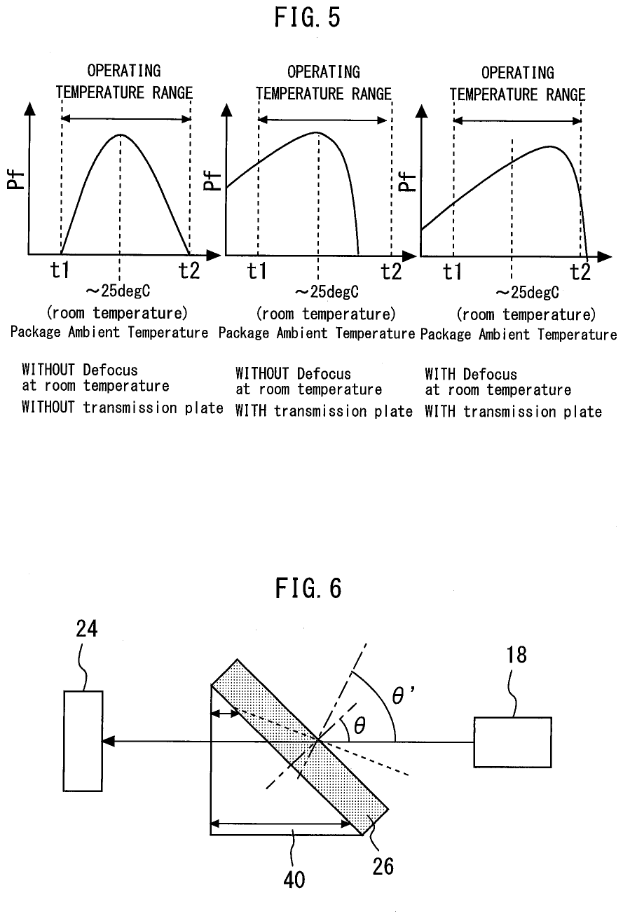

FIG. 5 is a diagram that shows the relationship between the module ambient temperature and the intensity (Pf) of the light signal coupled into the optical fiber. As the operating temperature range of the optical module 10, the temperature range from t1 to t2 is assumed. The graph on the left side shows the relationship between the module ambient temperature and the intensity (Pf) of the light signal coupled into the optical fiber in the case where the transmission plate 26 is removed from the configuration of FIG. 1 and defocusing of the optical fiber at room temperature is omitted. In this case, the peak of the light signal intensity (Pf) is obtained at room temperature. In addition, amounts of decrease in the light signal intensity Pf at an equivalent level will be observed as the ambient temperature deviates from the room temperature by the same degree to the high temperature or to the low temperature.

The graph on the right side of FIG. 5 shows the temperature dependence of the light signal intensity Pf in the above-described configuration of FIG. 1. Since defocusing of the optical fiber is implemented, the peak of the light signal intensity Pf is obtained on the high temperature side with reference to the room temperature. Also, since the transmission plate 26 is additionally provided, the injection current to the semiconductor laser element 18 is gradually reduced in response to the temperature rise. In the region where the temperature is low, the injection current to the semiconductor laser element 18 is increased and the intensity of the emitted light of the semiconductor laser element 18 becomes strong, so that the amount of decrease of the light signal intensity Pf becomes small. On the other hand, in the region where the temperature is high, the injection current to the semiconductor laser element 18 becomes small and the intensity of the emitted light of the semiconductor laser element 18 becomes weak, so that the amount of decrease of the light signal intensity Pf becomes large. However, when the optical fiber 28 is defocused such that the peak of the light signal intensity Pf can be obtained near the upper limit of the operating temperature range, it is made possible to suppress the amount of decrease of the light signal intensity Pf over the entire operating temperature range.

The graph in the center of FIG. 5 shows the temperature dependence of the light signal intensity Pf in the case where the above-described configuration of FIG. 1 is basically relied upon but defocusing of the optical fiber at room temperature is omitted. In this case, on the low temperature side with reference to the room temperature, the amount of decrease of the light signal intensity Pf can be made small. However, when the temperature becomes higher than the room temperature, the amount of decrease of the light signal intensity Pf becomes large, making it impossible to obtain a sufficient Pf near t2.

As has been explained with reference to FIG. 5, a high Pf can be maintained on the low temperature side by the transmission plate having the transmittance characteristics shown in the upper section of FIG. 3 and the APC control. In addition, when the temperature around the optical module is at the room temperature, a favorable Pf can be obtained over the entire operation temperature range by ensuring that the end surface position of the optical fiber 28 in the optical axis direction is defocused in the direction of the lens 22. Specifically, the position of the optical fiber 28 is defocused in the optical axis direction such that intensity of the light signal coupled into the optical fiber 28 becomes maximum at a temperature above the center temperature of the operation temperature range of the semiconductor laser element 18 and near the upper limit of the operation temperature range. By virtue of this, a favorable Pf can be obtained over the entire operation temperature range.

With regard to the transmission plate 26, in addition to the above-described effects, an effect of reducing the power consumption of the thermoelectric cooler 16 can also be obtained. Since the transmission plate 26 makes the injection current of the semiconductor laser element 18 smaller in response to the rise in the ambient temperature, heat generation of the semiconductor laser element 18 when the ambient temperature is a high temperature can be reduced. Accordingly, it is made possible to reduce the electrical power needed for the thermoelectric cooler 16 to cool the semiconductor laser element 18 at the time of a high temperature. Conversely, when the ambient temperature is a low temperature, the thermoelectric cooler 16 operates to warm the semiconductor laser element 18, but the heat generation of the semiconductor laser element 18 becomes large when the ambient temperature is a low temperature, so that the electrical power needed for the thermoelectric cooler 16 to warm the semiconductor laser element 18 becomes small.

As has been described in the foregoing, in the first embodiment, tracking error can be reduced by additionally providing the transmission plate 26 between the semiconductor laser element 18 and the monitor light-receiving element 24 and defocusing the optical fiber 28. Further, the power consumption of the thermoelectric cooler 16 can be reduced. Since the optical module in accordance with the following embodiments have many similar aspects to the first embodiment, description thereof will focus on the different aspects from the first embodiment.

### Second Embodiment

The optical module of the second embodiment has many common features that can also be seen in the first embodiment but differ from the first embodiment in that the optical fiber 28 is not defocused at room temperature. Specifically, in the second embodiment, aligning is performed so that a peak of the coupling efficiency can be obtained at room temperature. More specifically, the optical fiber 28 is provided at a position where the intensity of light signal coupled into the optical fiber 28 becomes maximum at the center temperature of the operation temperature range of the semiconductor laser element 18. For example, at room temperature, as illustrated in FIG. 2, it is ensured that the focal point of the emitted light and the end surface position of the optical fiber 28 generally agree with each other and the peak of the coupling efficiency is obtained.

In this case, the relationship between the module ambient temperature and the intensity of the light signal (P0 coupled into the optical fiber 28 will be observed, for example, as depicted by the graph in the center of FIG. 5. By virtue of the fact that the transmission plate 26 is provided, the amount of decrease in Pf on the low temperature side can be reduced. Accordingly, if improvement in the tracking error should be achieved only on the low temperature side, the optical module can be manufactured in a more simplified manner without performing defocusing.

### Third Embodiment

FIG. 6 is a diagram that illustrates part of the optical module in accordance with the third embodiment. The transmission plate 26 in the third embodiment is held by a support 40. The support 40 is formed by a material having a larger linear thermal expansion coefficient than the transmission plate 26. The support 40 is made of, for example, plastic. The support 40 can be fixed, for example, via a heat insulating member, to the heat dissipation block 17.

The support 40 has a thick portion and a thin portion in the direction of travel of the backlight. The support 40 having uneven thickness changes the position of the transmission plate 26 such that the angle of incidence of the backlight on the transmission plate 26 is increased in response to the temperature rise. For example, in FIG. 6, the angle of incidence of the backlight at room temperature on the transmission plate 26 is θ, and the angle of incidence of the backlight at a temperature higher than the room temperature on the transmission plate 26 becomes larger than θ. The light receiving surface of the transmission plate 26 receiving the backlight at the time of a high temperature is indicated by the broken line. The angle of incidence at this point is θ′ which is larger than θ.

FIG. 6 indicates the fact that the support 40 is thick at its lower portion in the direction of travel of the backlight and thin at its upper portion in the direction of travel of the backlight. The shape of the support 40 is, for example, a triangular prism. It should be noted that the support 40 depicted in FIG. 6 is merely an example and it is possible to adopt a support with other shapes that changes the position of the transmission plate such that the angle of incidence of the backlight on the transmission plate becomes larger as the temperature becomes higher.

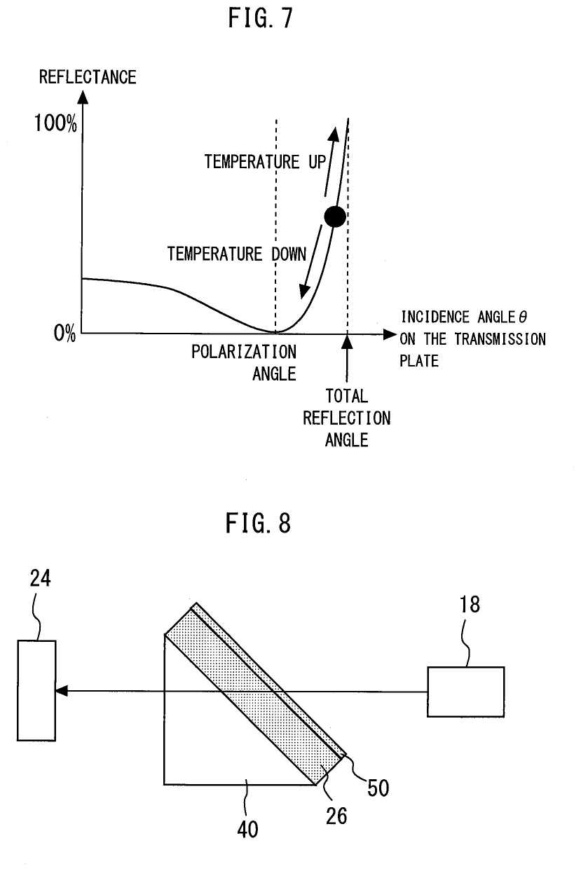

Here, the direction of polarization of the backlight of the semiconductor laser element 18 is P polarization. Also, the angle of incidence θ is set so that it resides between the angle of polarization and the angle of total reflection. FIG. 7 is a diagram that shows the relationship between the angle of incidence θ of the backlight of the semiconductor laser element 18 on the transmission plate 26 and the reflectance of the transmission plate 26. By providing the direction of polarization of the backlight as P polarization, a region where the amount of reflectance variation is steep is formed between the angle of polarization and the angle of total reflection. When the angle of incidence is set in this region, the reflectance of the transmission plate 26 changes steeply in response to temperature change. In other words, in response to the change in the angle of incidence, change in the injection current to the semiconductor laser element 18 by APC drive also becomes large. Hence, for example, it is made possible to increase the amount of compensation to compensate for the tracking error in the graph at the center or right side of FIG. 5.

### Fourth Embodiment

FIG. 8 is a diagram that illustrates part of the optical module in accordance with the fourth embodiment. A dielectric multilayer film 50 is formed on the transmission plate 26. The dielectric multilayer film 50 is configured to increase variation in the reflectance by the angle of incidence variation than in the third embodiment within the range of variation of the angle of incidence. The dielectric multilayer film 50 can be formed, for example, by laminating multiple layers of at least any one of titanium oxide, silicon oxide, niobium pentoxide, tantalum pentoxide, and magnesium fluoride. In addition to or in place of lamination of layers of one material, the dielectric multilayer film 50 may be formed by laminating layers of multiple materials. The dielectric multilayer film 50 has the property that reflectance changes sensitively according to the angle of incidence. By virtue of this, it is made possible to further increase the amount of compensation to compensate for the tracking error than in the third embodiment.

By forming the dielectric multilayer film 50, the direction of polarization of the backlight of the semiconductor laser element is not limited to P polarization and can be freely set. Hence, design flexibility to design the optical module can be increased.

### Fifth Embodiment

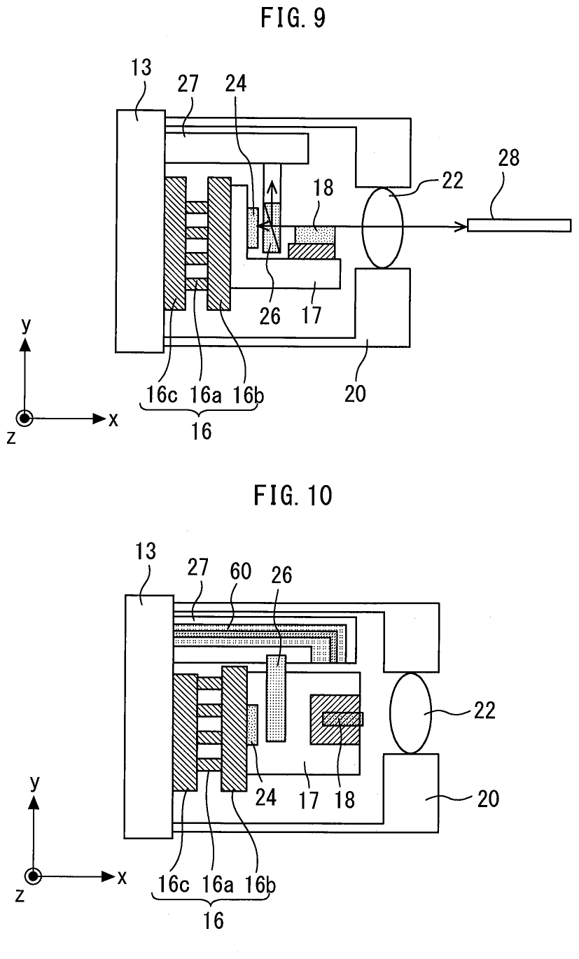

FIG. 9 is a cross-sectional view of the optical module in accordance with the fifth embodiment. The transmission plate 26 in the fifth embodiment reflects a component of the backlight that is not transmitted through the transmission plate 26 in a direction that is not parallel to the emitted light. For example, it is possible to provide a reflective surface that reflects a non-transmissive component, which is a component of the backlight that is not transmitted through the transmission plate 26, in a direction at 90° angle to the direction parallel to the emitted light. Such a reflective surface can be provided, for example, by the support 40 of FIG. 6 and a transmission plate 26 supported thereby. The configuration is not limited to this example, and it is possible to adopt any suitable configuration for reflecting the non-transmissive component in the direction that is not parallel to the emitted light.

According to the transmission plate 26 of the fifth embodiment, the above-described non-transmissive component can be prevented from interfering with the emitted light of the semiconductor laser element 18. Accordingly, the intensity distribution of the beams output from the lens 22 is closer to the single mode, facilitating optical axis adjustment for the optical fiber 28.

### Sixth Embodiment

FIG. 10 is a plan view of the optical module in accordance with the sixth embodiment. As has been discussed in the foregoing, the transmission plate 26 is fixed to the metal post 27. In the optical module of the sixth embodiment, a bridging substrate 60 is fixed to this metal post 27. The bridging substrate 60 has a high-frequency line for transmitting an electrical signal of the semiconductor laser element 18. Wired connection is provided between this high-frequency line and the semiconductor laser element 18. Accordingly, it is made possible to transmit high frequency electrical signal via the bridging substrate 60 to the semiconductor laser element 18.

By attaching both of the bridging substrate 60 and the transmission plate 26 to the metal post 27, it is made possible to achieve improvement in terms of tracking error and improvement of the high frequency characteristics. For example, the bridging substrate 60 may have an L-shape an end of which is exposed. By virtue of this, a space for mounting can be ensured in the metal post 27 to attach the transmission plate 26 thereto. Such a bridging substrate 60 with an L-shape makes it possible to position the high-frequency line at a location near the semiconductor laser element 18 and fix the transmission plate 26 to the metal post 27 at a location closer to the stem 13 than the end of the metal post 27.

It should be noted that the features of the optical modules of the above-described individual embodiments can be combined.

### DESCRIPTION OF SYMBOLS

10 optical module, 13 stem, 16 thermoelectric cooler, 18 semiconductor laser element, 20 cap, 22 lens, 24 monitor light-receiving element, 26 transmission plate

1. An optical module comprising:
a semiconductor laser element;
a thermoelectric cooler configured to controls the temperature of the semiconductor laser element at a constant level;
a lens configured to collect emitted light that is emitted from the semiconductor laser element;
a stem, the thermoelectric cooler is fixed to the stem;
a metal post fixed to the stem;
a cap configured to hold the lens and hermetically seal the semiconductor laser element, the cap is fixed to the stem;
a monitor light-receiving element configured to receive backlight of the semiconductor laser element;
a transmission plate arranged between the semiconductor laser element and the monitor light-receiving element and configured to attenuate the backlight according to decrease in a temperature of the transmission plate so as to cause the backlight to enter the monitor light-receiving element, the transmission plate is away from both the semiconductor laser element and the monitor light-receiving element, the transmission plate is fixed to the metal post;
a controller configured to control an injection current of the semiconductor laser element such that an output of the monitor light-receiving element is kept at a constant level; and
an optical fiber provided at a position where optical coupling takes place with the emitted light collected by the lens, wherein
a position of the optical fiber is defocused in an optical axis direction such that an intensity of a light signal coupled into the optical fiber becomes maximum at a temperature higher than the center temperature of an operation temperature range of the semiconductor laser element and near an upper limit of the operation temperature range.

2.-6. (canceled)

7. The optical module according to claim 1, wherein the transmission plate reflects a component of the backlight that is not transmitted through the transmission plate, the component being reflected in a direction which is not parallel to the emitted light.

8. The optical module according to claim 1, further comprising:
a bridging substrate fixed to the metal post, the bridging substrate having a high-frequency line configured to transmit an electrical signal of the semiconductor laser element.

9. The optical module according to claim 8, wherein
the bridging substrate has an L-shape an end of which is exposed, and
the transmission plate is fixed to the metal post at a location thereof closer to the stem than the end of the metal post.

10. The optical module according to claim 1, wherein the transmission plate is made of a borosilicate crown glass, synthetic quartz, or glass ceramics.

11. An optical module comprising:
a semiconductor laser element;
a thermoelectric cooler configured to controls the temperature of the semiconductor laser element at a constant level;
a lens configured to collect emitted light that is emitted from the semiconductor laser element;
a stem, the thermoelectric cooler is fixed to the stem;
a metal post fixed to the stem;
a cap configured to hold the lens and hermetically seal the semiconductor laser element, the cap is fixed to the stem;
a monitor light-receiving element configured to receive backlight of the semiconductor laser element;
a transmission plate arranged between the semiconductor laser element and the monitor light-receiving element and configured to attenuate the backlight according to decrease in a temperature of the transmission plate so as to cause the backlight to enter the monitor light-receiving element, the transmission plate is away from both the semiconductor laser element and the monitor light-receiving element, the transmission plate is fixed to the metal post;
a controller configured to control an injection current of the semiconductor laser element such that an output of the monitor light-receiving element is kept at a constant level; and
an optical fiber provided at a position where optical coupling takes place with the emitted light collected by the lens, wherein
the optical fiber is provided at a position where an intensity of a light signal coupled into the optical fiber becomes maximum at the center temperature of an operation temperature range of the semiconductor laser element.

12. The optical module according to claim 11, wherein the transmission plate reflects a component of the backlight that is not transmitted through the transmission plate, the component being reflected in a direction which is not parallel to the emitted light.

13. The optical module according to claim 11, further comprising:
a bridging substrate fixed to the metal post, the bridging substrate having a high-frequency line configured to transmit an electrical signal of the semiconductor laser element.

14. The optical module according to claim 13, wherein
the bridging substrate has an L-shape an end of which is exposed, and
the transmission plate is fixed to the metal post at a location thereof closer to the stem than the end of the metal post.

15. The optical module according to claim 11, wherein the transmission plate is made of a borosilicate crown glass, synthetic quartz, or glass ceramics.
